(19) United States
(12) Patent Application Publication
(10) Pub. No.: US 2012/0127791 A1
(43) Pub. Date: May 24, 2012

(54) NONVOLATILE MEMORY DEVICE, MEMORY SYSTEM COMPRISING SAME, AND METHOD OF PROGRAMMING SAME

(75) Inventor: Ji-Sang Lee, Iksan-si (KR)

(73) Assignee: SAMSUNG ELECTRONICS CO., LTD., Suwon-si (KR)

(21) Appl. No.: 13/236,711

(22) Filed: Sep. 20, 2011

(30) Foreign Application Priority Data
Nov. 24, 2010 (KR) 10-2010-0117667

(51) Int. Cl. G11C 16/10; G11C 16/04

(52) U.S. Cl. 365/185.03; 365/185.19

(57) ABSTRACT

A nonvolatile memory device is programmed using an incremental step pulse programming method comprising a plurality of program loops. Some program loops use a one step verification operation, and other program loops use a two step verification operation.

### CROSS-REFERENCE TO RELATED APPLICATIONS

This application claims priority under 35 U.S.C §119 to Korean Patent Application No. 10-2010-0117667 filed on Nov. 24, 2010, the disclosure of which is hereby incorporated by reference in its entirety.

### BACKGROUND OF THE INVENTION

Embodiments of the inventive concept relate generally to electronic memory technologies. More particularly, embodiments of the inventive concept relate to nonvolatile memory devices, memory systems comprising nonvolatile memory devices, and methods of programming nonvolatile memory devices.

Semiconductor memory devices can be roughly divided into two categories according to whether they retain stored data when disconnected from power. These categories include volatile memory devices, which lose stored data when disconnected from power, and nonvolatile memory devices, which retain stored data when disconnected from power. Examples of volatile memory devices include dynamic random access memory (DRAM) and static random access memory (SRAM), and examples of nonvolatile memory devices include electrically erasable programmable read-only memory (EEPROM), ferroelectric RAM (FRAM), phase change RAM (PRAM), magnetic random access memory (MRAM), and flash memory.

In recent years, the demand for nonvolatile memory has increased significantly. One driver of this increased demand has been the proliferation of mobile devices using nonvolatile memory, such as MP3 players, digital cameras, cellular phones, camcorders, flash memories, and solid-state disks.

Along with the increased demand for nonvolatile memory, there has been a demand for nonvolatile memory capable of storing greater amounts of data. One way that this demand has been addressed is by the development of nonvolatile memory devices capable of storing more than one bit of data per memory cell. Such memory devices are commonly referred to as multi-level cell (MLC) memory devices.

The memory cells in a MLC memory device typically have smaller read margins than those in a single-level cell (SLC) memory device. Accordingly, MLC memory devices are commonly programmed using an incremental step pulse programming (ISPP) scheme in which a program voltage is applied in successive program loops with an incrementally increasing magnitude.

### SUMMARY OF THE INVENTION

According to one embodiment of the inventive concept, a method is provided for programming a nonvolatile memory device using a stepwise increasing program voltage. The method comprises performing a program verification operation using a single verification voltage in at least one program loop, and performing a program verification operation using two verification voltages in program loops following the at least one program loop.

According to another embodiment of the inventive concept, a nonvolatile memory device comprises program control logic and a memory cell array storing data under control of the program control logic. The memory cell array is programmed by an incremental step pulse programming scheme comprising a plurality of program loops, and the program control logic performs a program verification operation using a 1-step verification operation in at least one program loop of the plurality of program loops and using a 2-step verification operation in program loops following the at least one program loop among the plurality of program loops.

According to another embodiment of the inventive concept, a memory system comprises a host system and a nonvolatile memory device. The nonvolatile memory device comprises program control logic and a memory cell array that stores data under control of the program control logic. The memory cell array is programmed by an incremental step pulse programming scheme comprising a plurality of program loops, and the program control logic performs a program verification operation using a 1-step verification operation in at least one program loop of the plurality of program loops and using a 2-step verification operation in program loops following the at least one program loop among the plurality of program loops.

### BRIEF DESCRIPTION OF THE DRAWINGS

The drawings illustrate selected embodiments of the inventive concept. In the drawings, like reference numbers indicate like features.

FIG. 1 is a block diagram of a nonvolatile memory device according to an embodiment of the inventive concept.

FIG. 2 is a diagram of program and verification voltages used in an ISPP scheme employing a 2-step verification operation.

FIG. 3 is a diagram of a program method using the ISPP scheme illustrated in FIG. 2.

FIG. 4 is a diagram of threshold voltage distributions of memory cells programmed to a target voltage by the ISPP scheme illustrated in FIG. 2.

FIG. 5 is a diagram of program and verification voltages of an ISPP scheme using a hybrid verify operation according to an embodiment of the inventive concept.

FIGS. 6 through 9 are diagrams for describing an ISPP scheme using the hybrid verification operation illustrated in FIG. 5.

FIG. 10 is a diagram for describing a method of determining a number of program loops not having a program verification operation with a main verification voltage in an ISPP scheme using the hybrid verification operation.

FIG. 11 is a block diagram of a solid-state drive comprising a nonvolatile memory device according to an embodiment of the inventive concept.

FIG. 12 is a block diagram of a solid-state drive controller illustrated in FIG. 11.

FIG. 13 is a block diagram of a data storage device comprising a nonvolatile memory device according to an embodiment of the inventive concept.

FIG. 14 is a block diagram of a memory card comprising a nonvolatile memory device according to an embodiment of the inventive concept.

FIG. 15 is a block diagram of a memory card connected to a host according to an embodiment of the inventive concept.

FIG. 16 is a block diagram of an electronic device comprising a nonvolatile memory device according to an embodiment of the inventive concept.

### DETAILED DESCRIPTION

Selected embodiments of the inventive concept are described below with reference to the accompanying drawings. These embodiments are presented as teaching examples and should not be construed to limit the scope of the inventive concept.

In the description that follows, the terms first, second, third, etc. are used to describe various features, but the described features should not be limited by these terms. Rather, these terms are used merely to distinguish between different features. Accordingly, a first feature could be termed a second feature without departing from the teachings of the inventive concept.

The terminology used herein is for the purpose of describing particular embodiments only and is not intended to be limiting of the inventive concept. As used herein, the singular forms “a”, “an” and “the” are intended to encompass the plural forms as well, unless the context clearly indicates otherwise. The terms “comprises” and/or “comprising” specify the presence of stated features, but they do not preclude the presence of additional features. The term “and/or” encompasses any and all combinations of one or more of the associated listed items.

Where an element or layer is referred to as being “on”, “connected to”, “coupled to”, or “adjacent to” another feature, it can be directly on, connected, coupled, or adjacent to the other feature, or intervening features may be present. In contrast, where a feature is referred to as being “directly on,” “directly connected to”, “directly coupled to”, or “immediately adjacent to” another feature, there are no intervening features present.

Unless otherwise defined, all terms (including technical and scientific terms) used herein have the same meaning as commonly understood by one of ordinary skill in the art. Terms such as those defined in commonly used dictionaries should be interpreted as having a meaning that is consistent with their meaning in the context of the relevant art and/or the present specification and will not be interpreted in an idealized or overly formal sense unless expressly so defined herein.

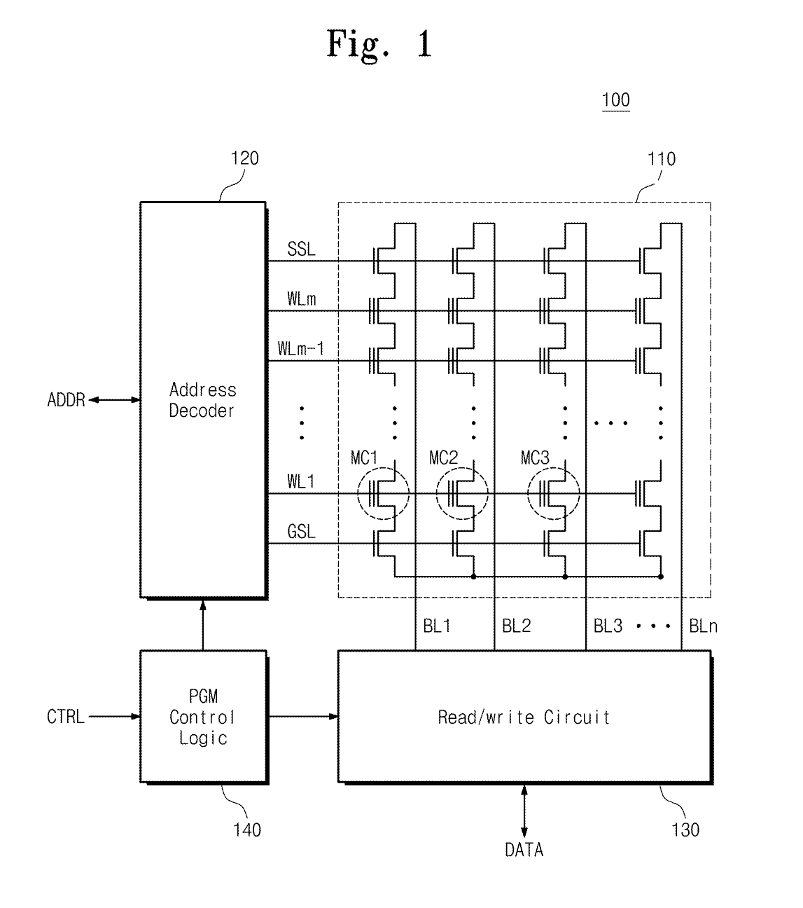

FIG. 1 is a block diagram of a nonvolatile memory device 100 according to an embodiment of the inventive concept. Referring to FIG. 1, nonvolatile memory device 100 comprises a memory cell array 110, an address decoder 120, a read/write circuit 130, and program control logic 140.

Memory cell array 110 comprises a plurality of memory cells each storing one-bit data or M-bit data (M>1) transferred from read/write circuit 130. A memory cell storing one-bit data is referred to as an SLC. A memory cell storing M-bit data is referred to as an MLC.

In some embodiments, memory cell array 110 is formed of a plurality of flash memory cells. However, in alternative embodiments, memory cell array 110 can be formed of other types of memory cells, such as FRAM cells, PRAM cells, MRAM cells, or RRAM cells.

Address decoder 120 is connected to memory cell array 110 via a string select line SSL, a ground select line GSL, and a plurality of word lines WL1 through WLm. Address decoder 120 receives an address ADDR from an external source. Address ADDR can comprise, for example, a row address and a column address. Address decoder 120 decodes the row address to select one of word lines WL1 through WLm. Address decoder 120 decodes the column address and transfers the decoded column address to read/write circuit 130. Read/write circuit 130 selects bit lines BL1 through BLn in response to the decoded column address.

Read/write circuit 130 is connected to the memory cell array 110 via bit lines BL1 through BLn. Read/write circuit 130 stores data from an external source in memory cell array 110. Read/write circuit 130 also reads data stored in memory cell array 110 and transfers the read data to an external destination.

Read/write circuit 130 typically comprises a column selecting gate, a page buffer, a data buffer, or similar features. Alternatively, read/write circuit 130 can comprise a column selecting gate, a write driver, a sense amplifier, a data buffer, or similar features. Program control logic 140 controls operations of nonvolatile memory device 100 in response to a control signal CTRL from an external source.

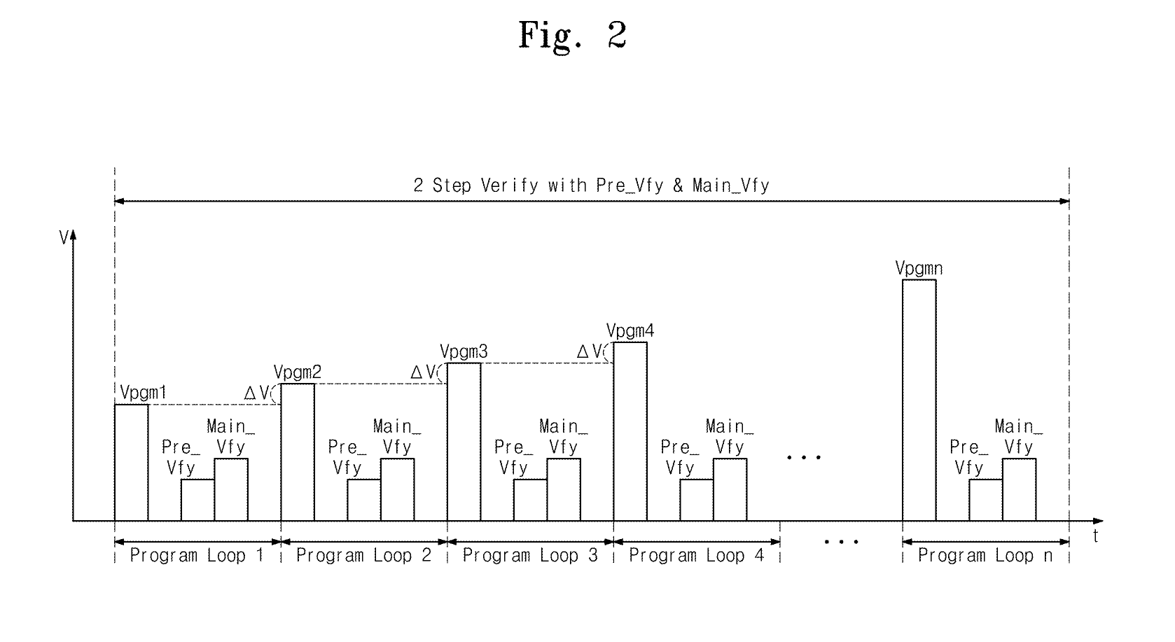

In a program operation, memory cells of memory cell array 110 are programmed using an ISPP scheme. In some embodiments, program control logic 140 controls nonvolatile memory device 100 to perform a program verification operation using two verification voltages. As the program verification operation is carried out with the two verification voltages, memory cells programmed to a target voltage form a narrower threshold voltage distribution compared with memory cells programmed via a program verification operation using one verification voltage. These embodiments will be more fully described with reference to FIGS. 2 through 4.

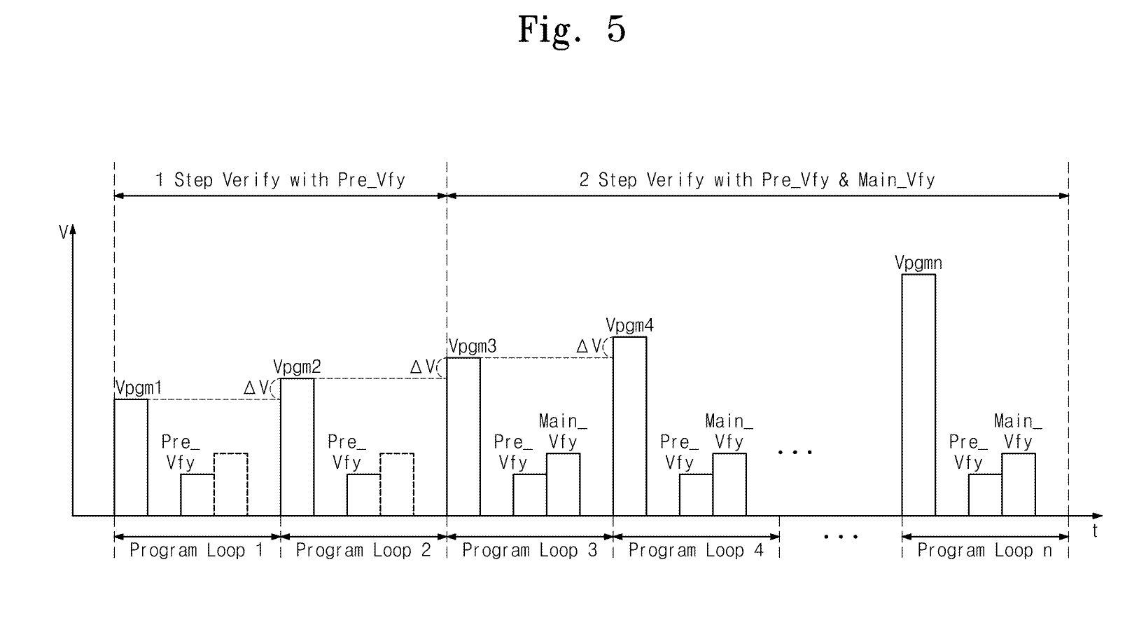

In some alternative embodiments, program control logic 140 controls nonvolatile memory device 100 to perform a program verification operation using one verification voltage at one or more initial program loops and to perform a program verification operation using two verification voltages at remaining program loops. In this case, memory cells programmed to a target voltage may have a narrower threshold voltage distribution compared with memory cells programmed via a program verification operation using one verification voltage. Further, where a program verification operation is carried out using one verification voltage at one or more initial program loops, a shorter time may be required to program memory cells to a target voltage compared with a program verification operation carried out using two verification voltages. These embodiments will be more fully described with reference to FIGS. 5 through 10.

FIGS. 2 through 4 are diagrams for describing an ISPP scheme in which a program verification operation is performed using two verification voltages. A program verification operation performed using two verification voltages will be referred to as a 2-step verify scheme.

FIG. 2 is a diagram of program and verification voltages according to an ISPP scheme using a 2-step verify operation. In FIG. 2, a horizontal axis represents a time and a vertical axis represents a voltage.

Referring to FIG. 2, an ISPP scheme using a 2-step verification operation is performed in a plurality of program loops. Each of the program loops involves one program voltage Vpgm and two verification voltages, and program voltage Vpgm increases by an increment ΔV with successive program loops. In each program loop, a program operation is performed with program voltage Vpgm, and then a program verification operation is performed with two verification voltages. The two verification voltages are referred to as a pre-verification voltage Pre_Vfy and a main verification voltage Main_Vfy, respectively.

In a first program loop, a program operation is carried out with a first program voltage Vpgm1, and a program verification operation is performed with verification voltages Pre_Vfy and Main_Vfy. Similarly, in a second program loop, a program operation is carried out with a second program voltage Vpgm2, and a program verification operation is performed with verification voltages Pre_Vfy and Main_Vfy. In this case, second program voltage Vpgm2 is greater than first program voltage Vpgm1 by increment ΔV.

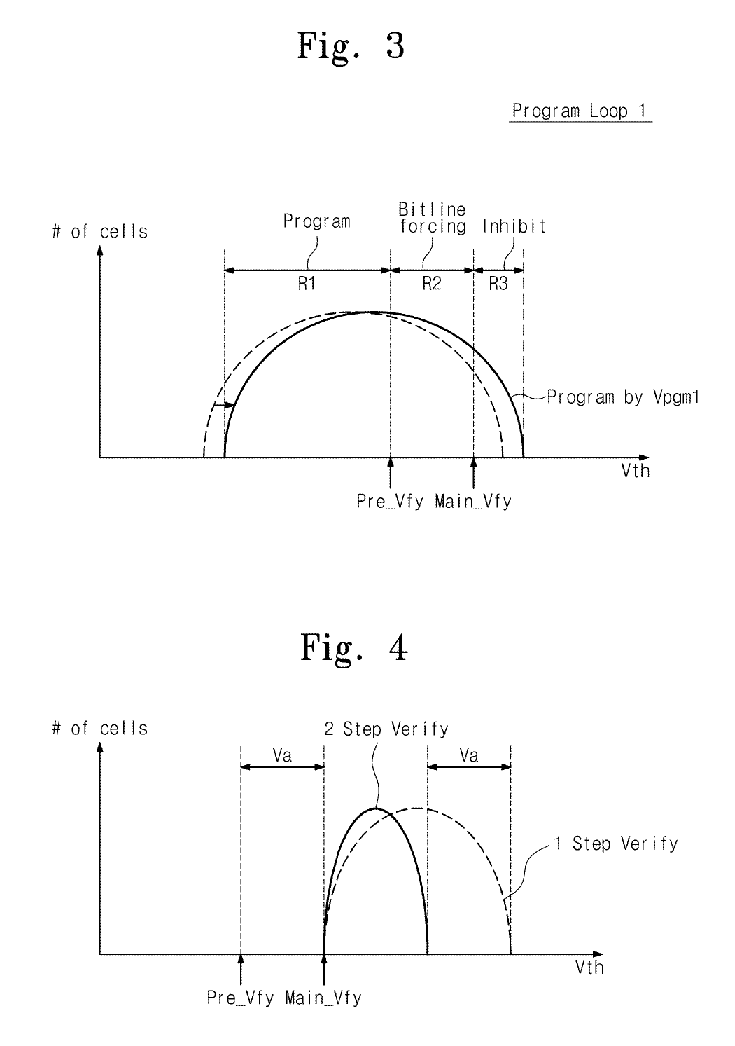

FIG. 3 is a diagram of a program method using the ISPP scheme of FIG. 2. In FIG. 3, a horizontal axis represents a threshold voltage, and a vertical axis represents a number of memory cells.

Referring to FIG. 3, a solid line indicates a distribution of threshold voltages of memory cells programmed by first program voltage Vpgm1 in the first program loop. Below, an ISPP scheme using a 2-step verification operation will be more fully described with reference to FIGS. 1 through 3. For explanation purposes, it will be assumed that a program operation is performed on memory cells connected with first word line WL1. Further, it is assumed that a target voltage (i.e., a target threshold voltage) of first through third memory cells MC1 through MC3 connected with first word line WL1 in FIG. 1 is greater than main verification voltage Main_Vfy.

Referring to FIGS. 1 and 3, a first program loop is performed using first program voltage Vpgm1. More specifically, write-requested data is provided to read/write circuit 130. Afterwards, a bit line bias operation is performed, in which first through third memory cells MC1 through MC3 are supplied with a ground voltage via respective bit lines. Following the bit line bias operation, first program voltage Vpgm1 is applied to selected memory cells via first word line WL. First program voltage Vpgm1 is supplied to first through third memory cells MC1 through MC3 via first word line WL1 to program these memory cells by F-N tunneling.

After the first program voltage Vpgm1, a program verification operation is performed with pre-verification voltage Pre_Vfy and main verification voltage Main_Vfy. The program verification operation determines whether memory cells programmed by first program voltage Vpgm1 belong to any region of first through third regions R1 through R3. More specifically, the program verification operation determines whether selected memory cells are turned on by pre-verification voltage Pre_Vfy supplied thereto via first word line WL1, and then it determines whether the selected memory cells are turned on by main verification voltage Main_Vfy supplied thereto via first word line WL1.

For explanation purposes, it is assumed that a result of the program verification operations using pre-verification voltage Pre_Vfy and main verification voltage Main_Vfy indicates whether threshold voltages of first through third memory cells MC1 through MC3 belong to first through third regions R1 to R3.

First region R1 is a region corresponding to memory cells each having a threshold voltage lower than pre-verification voltage Pre_Vfy. Second region R2 is a region corresponding to memory cells each having a threshold voltage higher than pre-verification voltage Pre_Vfy and lower than main verification voltage Main_Vfy. Third region R3 is a region corresponding to memory cells each having a threshold voltage higher than main verification voltage Main_Vfy.

After the program verification operation of the first program loop, a second program loop is carried out using second program voltage Vpgm2. More specifically, a bit line bias operation is performed, and then second program voltage Vpgm2 is supplied to selected memory cells via first word line WL1. In the bit line bias operation, a voltage supplied to each bit line may have a different level according to a threshold voltage of a selected memory cell connected to each bit line. An increasing width of a threshold voltage of a selected memory cell is adjusted by controlling a voltage supplied to a bit line according to a threshold voltage of the selected memory cell.

In this example, first memory cell MC1 has a threshold voltage in first region R1. In this case, a ground voltage of OV is supplied to a bit line corresponding to first memory cell MC1. Accordingly, where second program voltage Vpgm2 is supplied via first word line WL1, first memory cell MC1 is programmed by F-N tunneling. Because second program voltage Vpgm2 is higher than first program voltage Vpgm1 by the increment ΔV, a threshold voltage of the first memory cell MC1 increases accordingly.

Second memory cell MC2 has a threshold voltage in second region R2. In this case, a bit line forcing voltage Vf is applied to a bit line corresponding to second memory cell MC2. Herein, bit line forcing voltage Vf is a voltage (e.g., 1V) higher than a ground voltage and lower than a program-inhibition voltage Vcc.

Accordingly, where second program voltage Vpgm2 is supplied via first word line WL1, a voltage difference of (Vpgm2−Vf) (or, Vpgm1+ΔV−Vf) is applied between a control gate of second memory cell MC2 and a well. Consequently, a threshold voltage of second memory cell MC2 increases by a small amount compared with a threshold voltage of first memory cell MC1.

Third memory cell MC3 has a threshold voltage in third region R3. In this case, a program-inhibition voltage Vcc is applied to a bit line corresponding to third memory cell MC3. Where second program voltage Vpgm2 is supplied via the first word line WL1, third memory cell MC3 is program inhibited.

After the program operation is carried out with second program voltage Vpgm2, a program verification operation is performed with pre-verification voltage Pre_vfy and main verification voltage Main_Vfy. Thereafter, the remaining program loops are performed.

FIG. 4 is a diagram of threshold voltage distributions of memory cells programmed to a target voltage by the ISPP scheme of FIG. 2. In FIG. 4, a horizontal axis represents a threshold voltage Vth and a vertical axis represents a number of memory cells.

Referring to FIG. 4, threshold voltages of memory cells programmed to a target voltage by an ISPP scheme using a 2-step verification operation form a narrower distribution than that using a 1-step verification operation. The reason, as described in FIG. 3, is that threshold voltages of memory cells corresponding to first region R1 increase according to an increment ΔV of a program voltage while threshold voltages of memory cells corresponding to the second region R2 increase by lower amount.

In this case, a difference of a threshold voltage distribution of memory cells programmed to a target voltage by the ISPP scheme using the 2-step verification operation and a threshold voltage distribution of memory cells programmed to a target voltage by the ISPP scheme using the 1-step verification operation may correspond to a voltage difference Va between pre-verification voltage Pre_Vfy and main verification voltage Main_Vfy, for example.

As described above, the ISPP scheme using the 2-step verification operation forms a threshold voltage distribution narrower than that using the 1-step verification operation. However, because two program verification operations are carried out in every program loop, the execution time for the ISPP scheme using the 2-step verification operation may be than that of the 1-step verification operation.

FIG. 5 is a diagram of program and verification voltages of an ISPP scheme using a hybrid verification operation according to another embodiment of the inventive concept. In FIG. 5, a horizontal axis represents a time and a vertical axis represents a voltage. The ISPP scheme of FIG. 5 is similar to that using a 2-step verification operation. Thus, the following description will focus on differences between the ISPP scheme using the hybrid verification operation and the ISPP scheme using the 2-step verification operation.

Referring to FIG. 5, an ISPP scheme using the hybrid verification operation comprises program loops for performing a program verification operation according to the 1-step verification operation and program loops for performing a program verification operation according to the 2-step verification operation. That is, the ISPP scheme using the hybrid verification operation may comprise a group of first through k-th program loops in which a program verification operation is carried out according to the 1-step verify operation, and a group of remaining program loops in which a program verification operation is carried out according to the 2-step verify operation. In the example of FIG. 5, k is equal to 2.

In the ISPP scheme using the hybrid verification operation, a program verification operation using pre-verification voltage Pre_vfy is carried out in each of the first through k-th program loops. In other words, no program verification operations using main verification voltage Main_vfy are made in the first through k-th program loops.

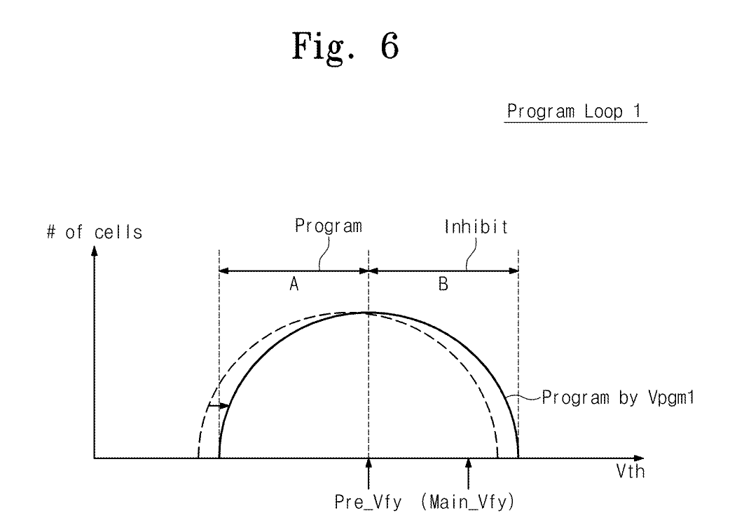

In the ISPP scheme using the hybrid verification operation, an execution time of the first through k-th program loops is shortened compared with that using the 2-step verification operation. The ISPP scheme using the hybrid verification operation will be more fully described with reference to FIGS. 6 through 9.

Meanwhile, the ISPP scheme using the hybrid verification operation, the number (i.e., k) of program loops not having a program verification operation with main verification voltage Main_Vfy can be adjusted properly. Where “k” is greater than a predetermined value, memory cells programmed to a target voltage by the ISPP scheme using the hybrid verification operation may form a threshold voltage distribution identical or similar to that using the 1-step verification operation.

Thus, “k” may be set to a predetermined value such that a threshold voltage distribution of memory cells programmed to a target value by the ISPP scheme using the hybrid verification operation becomes narrow compared with that using the 1-step verification operation. For example, the higher a bit line forcing voltage Vf, the greater the value of “k”. The lower the increment “V” of a program voltage, the greater the value of “k”. This will be more fully described with reference to FIGS. 6 through 10.

FIGS. 6 through 9 are diagrams for describing the ISPP scheme using the hybrid verification operation of FIG. 5. For explanation purposes, it will be assumed that no program verification operation using main verification voltage Main_Vfy is performed in the first and second program loops as illustrated in FIG. 5.

Referring to FIG. 6, a solid line represents a threshold voltage distribution of memory cells programmed by first program voltage Vpgm1 in the first program loop.

In the first program loop, if a program operation is carried out by first program voltage Vpgm1, a program verification operation may be performed using pre-verification voltage Pre_Vfy. In particular, the program verification operation may determine whether memory cells programmed by first program voltage Vpgm1 belong to any one of regions ‘A’ and ‘B’ by applying pre-verification voltage Pre_vfy to selected memory cells via a selected word line. Herein, the ‘A’ region represents a region of memory cells each having a threshold voltage lower than pre-verification voltage Pre_Vfy. The ‘B’ region represents a region of memory cells each having a threshold voltage higher than pre-verification voltage Pre_Vfy.

Memory cells determined to belong to the ‘A’ region in the first program loop are programmed in a next program loop, i.e., the second program loop. Memory cells judged to belong to the ‘B’ region in the first program loop are program inhibited in the second program loop.

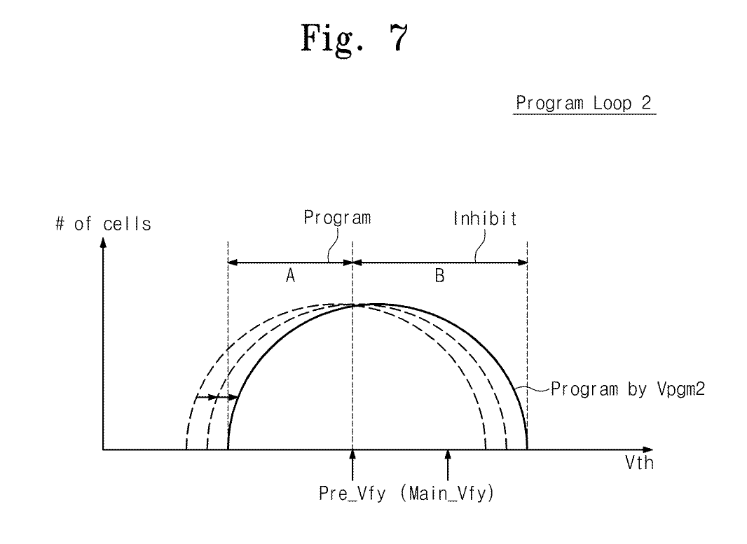

Referring to FIG. 7, a solid line represents a threshold voltage distribution of memory cells programmed by second program voltage Vpgm2 in the second program loop.

In a bit line bias operation of the second program loop, a ground voltage is applied to bit lines of memory cells judged to belong to the ‘A’ region at in first program loop. Thus, the memory cells judged to belong to the ‘A’ region in the first program loop are programmed with second program voltage Vpgm2 in the second program loop. In this case, threshold voltages of memory cells within the ‘A’ region increase according to increment ΔV of the program voltage.

In the bit line bias operation of the second program loop, a program-inhibition voltage is applied to bit lines of memory cells judged to belong to the ‘B’ region in the first program loop. Thus, the memory cells judged to belong to the ‘B’ region in the first program loop are not programmed although second program voltage Vpgm2 is applied to a selected word line in the second program loop.

Meanwhile, after a program operation is carried out with second program voltage Vpgm2 in the second program loop, a program verification operation is performed with pre-verification voltage Pre_Vfy. That is, it is judged whether memory cells programmed by second program voltage Vpgm2 belong to either the ‘A’ region or the ‘B’ region.

Memory cells judged to belong to the ‘A’ region in the second program loop are programmed in a next program loop, that is, the third program loop. Memory cells judged to belong to the ‘B’ region in the second program loop are program inhibited in the third program loop.

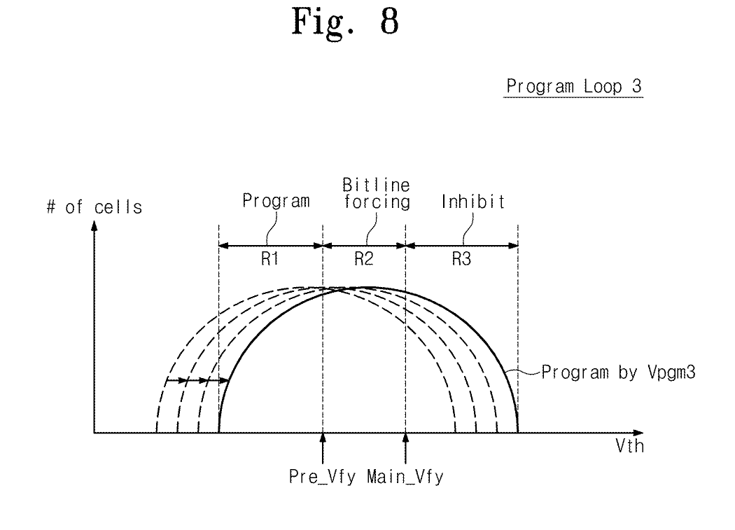

Referring to FIG. 8, a solid line represents a threshold voltage distribution of memory cells programmed by third program voltage Vpgm3 in the third program loop.

In a bit line bias operation of the third program loop, a ground voltage is applied to bit lines of memory cells judged to belong to the ‘A’ region in the third program loop. Thus, the memory cells judged to belong to the ‘A’ region in the second program loop are programmed with third program voltage Vpgm3 of the third program loop.

In the bit line bias operation of the third program loop, a program-inhibition voltage Vcc is applied to bit lines of memory cells judged to belong to the ‘B’ region in the second program loop. Thus, the memory cells judged to belong to the ‘B’ region in the second program loop are not programmed although third program voltage Vpgm3 is applied to a selected word line in the third program loop.

Meanwhile, after a program operation is performed with third program voltage Vpgm3 in the third program loop, a program verification operation is performed with pre-verification voltage Pre_Vfy and main verification voltage Main_Vfy. Unlike the first and second program loops, a program verification operation is carried out using main verification voltage Main_Vfy in the third program loop. In this case, a program verification operation using pre-verification voltage Pre_Vfy and main verification voltage Main_Vfy judges whether threshold voltages of memory cells programmed by the third program voltage Vpgm3 belong to any of first through third regions R1 through R3.

In a bit line bias operation of a next program loop, i.e., the fourth program loop, a ground voltage is applied to bit lines of memory cells judged to belong to first region R1 in the third program loop. Thus, threshold voltages of memory cells judged to belong to first region R1 in the third program loop increase according to an increment ΔV of a program voltage in the fourth program loop (refer to FIG. 5).

In the bit line bias operation of the fourth program loop, bit line forcing voltage Vf is applied to bit lines of memory cells judged to belong to second region R2 in the third program loop. Thus, threshold voltages of the memory cells judged to belong to second region R2 in the third program loop increase by a smaller amount than increment ΔV.

In the bit line bias operation of the fourth program loop, a program inhibition voltage Vcc is applied to bit lines of memory cells judged to belong to third region R3 in the third program loop. Thus, of memory cells judged to belong to third region R3 in the third program loop are program-inhibited in the fourth program loop.

Meanwhile, operations of fourth through n-th program loops are performed identically to those of program loops using the 2-step verification operation described in relation to FIGS. 2 through 4, so a description thereof will omitted for the sake of brevity.

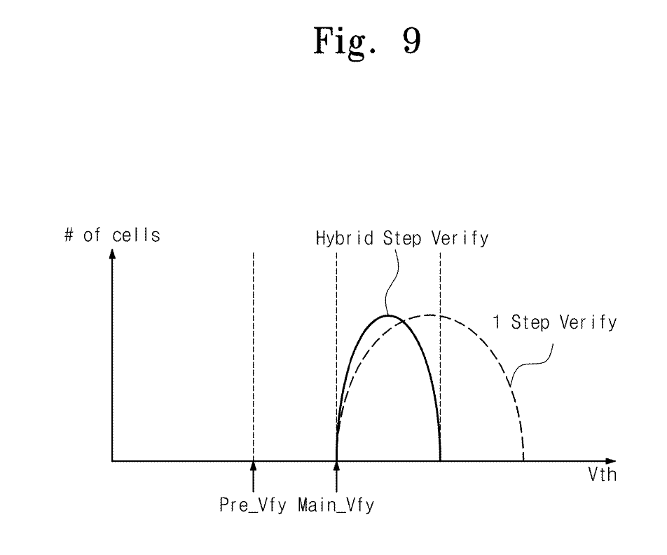

Referring to FIG. 9, there is illustrated a threshold voltage distribution of memory cells programmed to a target voltage by the ISPP scheme using the hybrid verification operation. Because the 2-step verification operation is applied to the third through n-th program loops, a threshold voltage distribution of memory cells programmed to a target voltage by the ISPP scheme using the hybrid verification operation is narrower than that using a 1-step verification operation.

Further, because the 1-step verification operation is applied to the first and second program loops, the ISPP scheme using the hybrid verification operation is performed rapidly compared with the ISPP scheme using the 2-step verification operation.

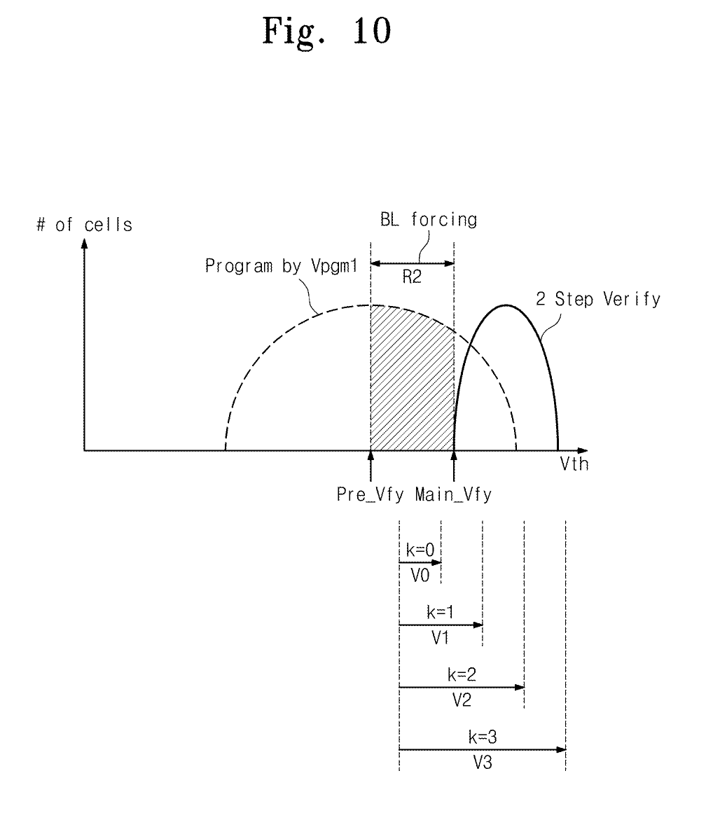

FIG. 10 is a diagram for describing a method of determining a number of program loops not having a program verification operation with a main verification voltage in an ISPP scheme using the hybrid verification operation. In FIG. 10, a horizontal axis represents a threshold voltage Vt, and a vertical axis represents a number of memory cells.

Referring to FIG. 10, a dotted line indicates a threshold voltage distribution of memory cells programmed by first program voltage Vpgm1. A solid line indicates a threshold voltage distribution of memory cells programmed to a target voltage by an ISPP scheme using a 2-step verification operation.

In FIG. 10, a value “k” indicates the number of program loops not having a program verification operation using main verification voltage Main_Vfy. For example, “k=1” indicates that one program loop (i.e., a first program loop) does not accompany a program verification operation using main verification voltage Main_Vfy. Similarly, “k=2” indicates that two program loops (i.e., first and second program loops) do not accompany a program verification operation using main verification voltage Main_Vfy. Meanwhile, “k=0” indicates that all program loops accompany a program verification operation using main verification voltage Main_Vfy as well as a program verification operation using pre-verification voltage Pre_Vfy.

Where “k=1”, no program verification operation using main verification voltage Main_Vfy is performed in the first program loop. That is, a program verification operation using pre-verification voltage Pre_Vfy is performed in the first program loop. Thus, memory cells (shown in a shaded region of FIG. 10) having a threshold voltage within second region R2 and programmed by first program voltage Vpgm1 in the first program loop, are program-inhibited in the second program loop and then programmed by third program voltage Vpgm3 of the third program loop.

In this case, memory cells within second region R2 are supplied with bit line forcing voltage Vf via bit lines in the third program loop and with third program voltage Vpgm3 via a word line. Thus, a voltage difference of (Vpgm3−Vf) (=Vpgm1+2ΔV−Vf) is applied between a control gate of each memory cell in second region R2 and a well. Accordingly, where (2ΔV−Vf)<ΔV, threshold voltages of memory cells in second region R2 increase by a voltage lower than increment ΔV, according to first program voltage Vpgm1.

As illustrated in FIG. 10, where “k=1”, threshold voltages of memory cells programmed to first region R1 by first program voltage Vpgm1 increase by ‘V1’ by third program voltage Vpgm3. The increased threshold voltages belong to a threshold voltage distribution of memory cells programmed to a target voltage by the ISPP scheme using the 2-step verification operation. Thus, where “k=1”, a threshold voltage distribution of memory cells programmed to a target voltage by the ISPP scheme using the hybrid verification operation is identical to that using the 2-step verification operation.

Likewise, where “k=p” (p being an integer of 1 or more), the first through p-th program loops do not have a program verification operation using main verification voltage Main_Vfy. In this case, memory cells programmed to second region R2 by (p+1)-th program voltage Vpgm_p+1 of a (p+1)-th program loop are supplied with bit line forcing voltage Vf via bit lines in a (p+2)-th program loop and with a (p+2)-th program voltage Vpgm_p+2 via a word line. Thus, a voltage difference of (Vpgm_p+2−Vf) (=Vpgm1+(p+1)ΔV−Vf) is applied to a well and a control gate of each memory cell within second region R2. Accordingly, where (p+1)ΔV−Vf<ΔV, threshold voltages of memory cells within second region R2 increase by a voltage lower than increment ΔV, according to first program voltage Vpgm1.

As a result, where “k=p”, the condition of (p+1) ΔV−Vf<ΔV is satisfied such that a threshold voltage distribution of memory cells programmed to a target voltage by the ISPP scheme using the hybrid verification operation becomes narrow compared with that using the 1-step verification operation. Thus, because p<VVΔV, “k=p” has a large value as bit line forcing voltage Vf increases and as the increment ΔV of a program voltage increases.

Meanwhile, referring to FIG. 10, where “k=3”, a threshold voltage distribution of memory cells programmed to a target voltage by the ISPP scheme using the hybrid verification operation is assumed to be identical to that using the 2-step verification operation. However, the value “k” is varied due to factors such as program disturbance.

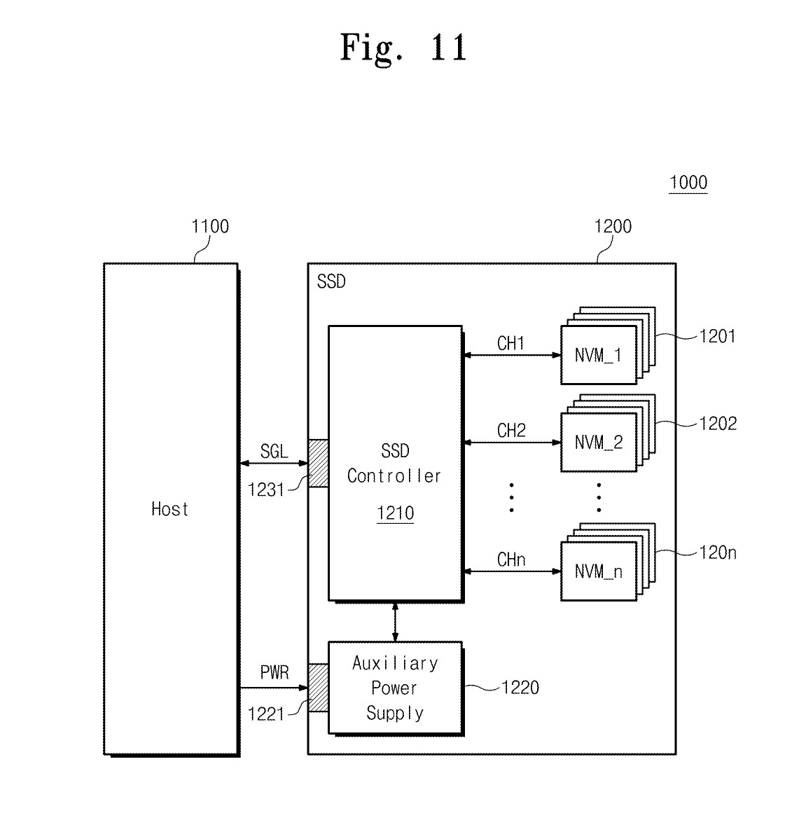

FIG. 11 is a block diagram of a solid-state drive comprising a nonvolatile memory device according to an embodiment of the inventive concept. Referring to FIG. 11, a solid-state drive (SSD) system 1000 comprises a host 1100 and an SSD 1200. SSD 1200 exchanges signals with host 1100 via a signal connector 1231 and receives power via a power connector 1221. SSD 1200 comprises a plurality of nonvolatile memory device 1201 through 120n, an SSD controller 1210, and an auxiliary power supply 1220.

Nonvolatile memory devices 1201 through 120n are used as storage media, and they typically comprise large-capacity flash memory devices. Alternatively, nonvolatile memory devices 1201 through 120n can comprise other forms of nonvolatile memory, such as PRAM, MRAM, or ReRAM. In FIG. 11, at least one nonvolatile memory device uses an ISPP scheme using a hybrid verification operation described in FIGS. 5 through 10.

Nonvolatile memory devices 1201 through 120n are connected with SSD controller 1210 through a plurality of channels CH1 through CHn, where each channel is connected to one or more memory devices. Memory devices connected with one channel are generally connected to the same data bus.

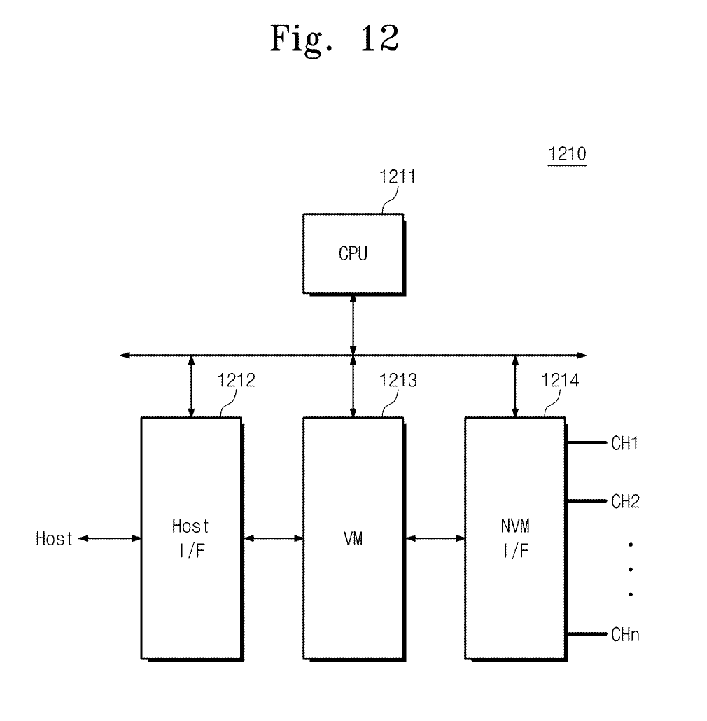

SSD controller 1210 exchanges a signal SGL with host 1100 via signal connector 1231. Signal SGL typically comprises information such as a command, an address, or data. SSD controller 1210 is configured to write or read out data to or from a memory device in response to a command from host 1100. Various features of SSD controller 1210 will be more fully described with reference to FIG. 12.

Auxiliary power supply 1220 is connected with host 1100 via power connector 1221. Auxiliary power supply 1220 is charged by power PWR from host 1100. In general, auxiliary power supply 1220 can be placed inside or outside SSD 1200. For example, auxiliary power supply 1220 can be located on a main board to supply an auxiliary power to SSD 1200.

FIG. 12 is a block diagram of a SSD controller 1210 shown in FIG. 11. Referring to FIG. 12, SSD controller 1210 comprises a CPU 1211, a host interface 1212, a volatile memory 1213, and an NVM interface 1214.

CPU 1211 is configured to analyze and process signal SGL received from host 1100 (refer to FIG. 10). CPU 1211 controls host 1100 or nonvolatile memories 1201 through 120n via host interface 1212 or NVM interface 1214. CPU 1211 controls nonvolatile memory devices 1201 through 120n based on the firmware for driving SSD 1200.

Host interface 1212 provides an interface between SSD 1200 and host 1100 according to the protocol of host 1100. Host interface 1212 can communicate with host 1100 using one of various standard interfaces, such as universal serial bus (USB), small computer system interface (SCSI), PCI express, AT Attachment (ATA), parallel ATA (PATA), serial ATA (SATA), or serial attached SCSI (SAS). Further, host interface 1212 may support a disk emulation function to enable SSD 1200 to operate as a hard disk drive (HDD).

Volatile memory device 1213 is configured to temporarily store write data provided from host 1100 or data read out from a nonvolatile memory device. For example, volatile memory device 1213 may store metadata or cache data being stored in nonvolatile memory devices 1201 through 120n. In a sudden power-off operation, the meta data or cache data stored in volatile memory 1213 can be stored in nonvolatile memory devices 1201 through 120n. Volatile memory device 1213 can comprise, for example, DRAM or SRAM.

NVM interface 1214 is configured to scatter data transferred from volatile memory device 1213 to channels CH1 through CHn. NVM interface 1214 transfers data read out from nonvolatile memory devices 1201 through 120n to volatile memory device 1213. In certain embodiments, NVM interface 1214 takes the form of a NAND flash memory interface. Accordingly, SSD controller 1210 can perform program, read, and erase operations according to the NAND flash memory interface.

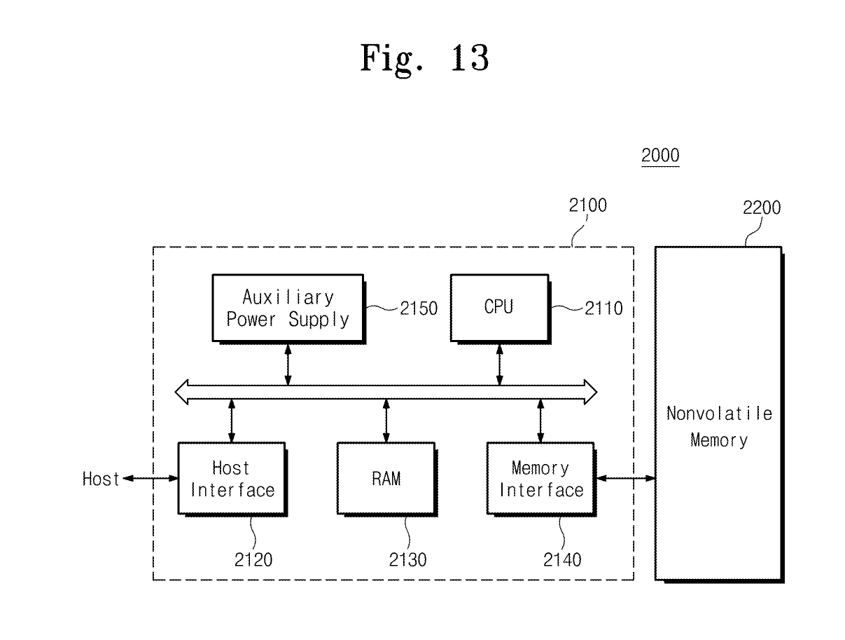

FIG. 13 is a block diagram of a data storage device 2000 comprising a nonvolatile memory device according to an embodiment of the inventive concept. Referring to FIG. 13, data storage device 2000 comprises a memory controller 2100 and a nonvolatile memory 2200. Data storage device 2000 can comprise various forms of storage media such as memory cards (e.g., SD, MMC, etc.), and removable storage devices (e.g., USB memory, etc.).

Referring to FIG. 13, memory controller 2100 comprises a CPU 2110, a host interface 2120, a RAM 2130, a flash interface 2140, and an auxiliary power supply 2150. Auxiliary power supply 2150 is placed inside or outside memory controller 2100.

Data storage device 2000 is used via interconnection with a host. Data storage device 2000 exchanges data with the host via host interface 2120 and with nonvolatile memory 2200 via flash interface 2140. Data storage device 2000 is powered by the host. Nonvolatile memory device 2200 of FIG. 13 uses an ISPP scheme using a hybrid verification operation described in FIGS. 5 through 10.

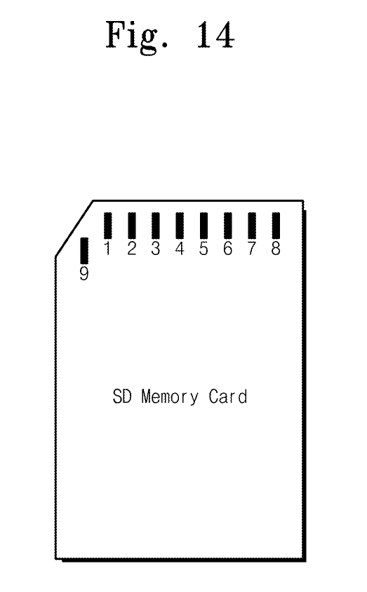

FIG. 14 is a block diagram of a memory card comprising a nonvolatile memory device according to an embodiment of the inventive concept. The memory card of FIG. 14 has a standard SD card interface having nine pins. More specifically, the SD card comprises four data pins (e.g., 1, 7, 8, and 9), one command pin (e.g., 2) one clock pin (e.g., 5), and three power pins (e.g., 3, 4, 6).

Command and response signals are transferred via command pin 2. In general, the command signals can be sent from a host to the memory card, and the response signals can be sent from the memory card to the host.

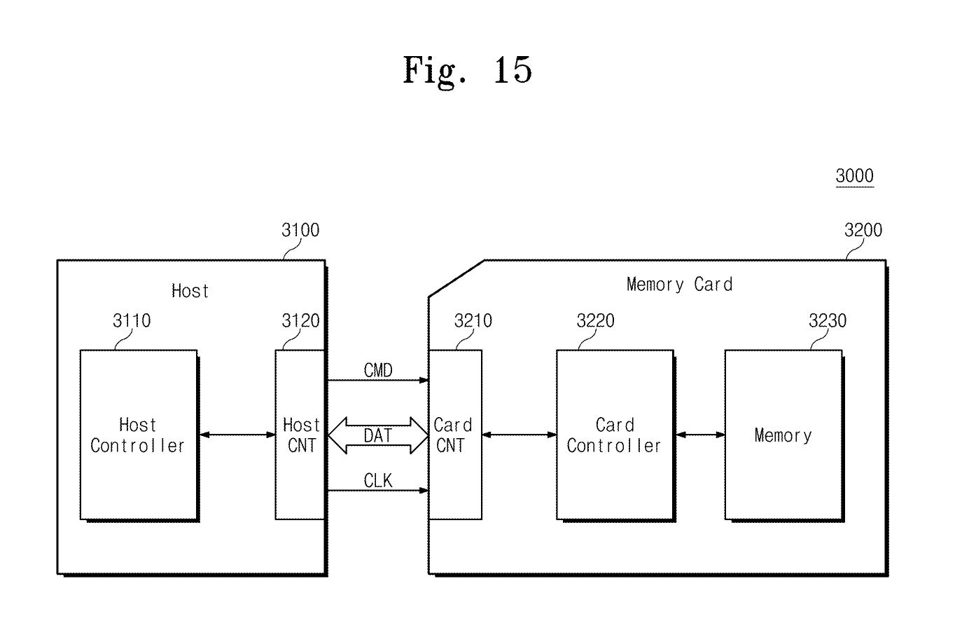

FIG. 15 is a block diagram of a memory card connected with a host. The memory card of FIG. 15 can be an SD card such as that illustrated in FIG. 14.

Referring to FIG. 15, a memory card system 3000 comprises a host 3100 and a memory card 3200. Host 3100 comprises a host controller 3110 and a host connection unit 3120. Memory card 3200 comprises a card connection unit 3210, a card controller 3220, and a memory 3230.

The host and card connection units 3120 and 3210 are formed of a plurality of pins including a command pin, a data pin, a clock pin, a power pin, and the like. The number of pins can differ according to a memory card type. For example, the SD card of FIG. 14 has nine pins.

Host 3100 is configured to write data in memory card 3200 and to read data from memory card 3200. Host controller 3110 sends a command (e.g., a write command), a clock signal CLK generated by a clock generator (not shown) of host 3100, and data to memory card 3200 via host connection unit 3120.

Card controller 3220 stores data in memory 3230 in response to a write command CMD received via card connection unit 3210. The storing of data in memory 3230 is performed in synchronization with a clock signal generated by a clock generator (not shown) within card controller 3220. Memory 3230 stores data transferred from host 3110. For example, image data is stored in memory 3230 if host 3100 is a digital camera. An ISPP scheme using a hybrid verification operation described in FIGS. 5 through 10 can be employed by memory 3230.

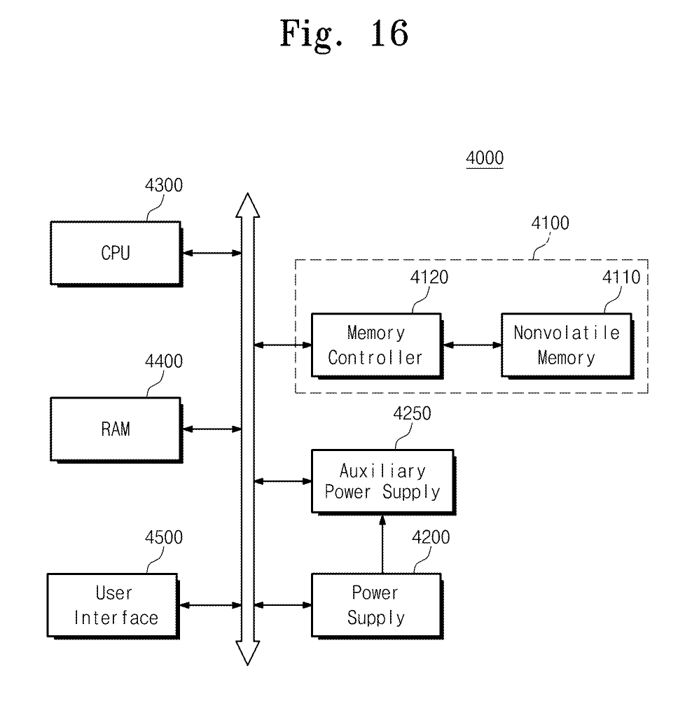

FIG. 16 is a block diagram of an electronic device 4000 comprising a nonvolatile memory device according to an embodiment of the inventive concept. Electronic device 4000 can take the form of a handheld electronic device such as a personal computer, a notebook computer, a cellular phone, a personal digital assistant (PDA), or a camera, for example.

Referring to FIG. 16, electronic device 4000 comprises a semiconductor memory device 4100, a power supply 4200, an auxiliary power supply 4250, a CPU 4300, a RAM 4400, and a user interface 4500. Semiconductor memory device 4100 comprises a nonvolatile memory 4110 and a memory controller 4120. An ISPP scheme using a hybrid verification operation described in FIGS. 5 through 10 can be used in nonvolatile memory 4110.

The above-disclosed subject matter is to be considered illustrative and not restrictive, and the appended claims are intended to cover all such modifications, enhancements, and other embodiments, which fall within the scope of the inventive concept. To the maximum extent allowed by law, the scope of the inventive concept is to be determined by the broadest permissible interpretation of the following claims and their equivalents, and shall not be restricted or limited by the foregoing detailed description.

What is claimed is:

1. A method of programming a nonvolatile memory device using a stepwise increasing program voltage, comprising:
performing a program verification operation using a single verification voltage in at least one program loop; and
performing a program verification operation using two verification voltages in program loops following the at least one program loop.

2. The method of claim 1, wherein the at least one program loop comprises a program verification operation using a first verification voltage, and
wherein the program loops following the at least one program loop comprise a program verification operation using the first verification voltage and a second verification voltage higher than the first verification voltage.

3. The method of claim 2, wherein during the at least one program loop, a ground voltage is applied to bit lines connected with memory cells determined to have a threshold voltage lower than the first verification voltage, and a program inhibition voltage is applied to bit lines connected with memory cells determined to have a threshold voltage higher than the first verification voltage.

4. The program method of claim 2, wherein during the program loops following the at least one program loop, a ground voltage is applied to bit lines connected with memory cells determined to have a threshold voltage lower than the first verification voltage, a bit line forcing voltage is applied to bit lines connected with memory cells determined to have a threshold voltage higher than the first verification voltage and lower than the second verification voltage, and a program inhibition voltage is applied to bit lines connected with memory cells determined to have a threshold voltage higher than the second verification voltage.

5. The program method of claim 4, wherein the number of the at least one program loop increases as an increment of a program voltage becomes lower.

6. The program method of claim 5, wherein the number of the at least one program loop increases as the bit line forcing voltage becomes higher.

7. The program method of claim 1, wherein the nonvolatile memory device comprises memory cells each storing at least two bits of data.

8. A nonvolatile memory device comprising:
program control logic; and
a memory cell array storing data under control of the program control logic,
wherein the memory cell array is programmed by an incremental step pulse programming (ISPP) scheme comprising a plurality of program loops, and
wherein the program control logic performs a program verification operation using a 1-step verification operation in at least one program loop of the plurality of program loops and using a 2-step verification operation in program loops following the at least one program loop among the plurality of program loops.

9. The nonvolatile memory device of claim 8, wherein the at least one program loop comprises a first program loop among the plurality of program loops.

10. The nonvolatile memory device of claim 8, wherein the 1-step verification operation is performed with a first verification voltage, and the 2-step verification operation is performed with the first verification voltage and a second verification voltage higher than the first verification voltage.

11. The nonvolatile memory device of claim 10, wherein in the 1-step verification operation, a ground voltage is applied to bit lines connected with memory cells determined to have a threshold voltage lower than the first verification voltage and a program inhibition voltage is applied to bit lines connected with memory cells determined to have a threshold voltage higher than the first verification voltage.

12. The nonvolatile memory device of claim 10, wherein in the 2-step verification operation, a ground voltage is applied to bit lines connected with memory cells determined to have a threshold voltage lower than the first verification voltage, a bit line forcing voltage is applied to bit lines connected with memory cells determined to have a threshold voltage higher than the first verification voltage and lower than the second verification voltage, and a program inhibition voltage is applied to bit lines connected with memory cells determined to have a threshold voltage higher than the second verification voltage.

13. The nonvolatile memory device of claim 12, wherein the number of program loops accompanying a program verification operation executed by the 1-step verification operation increases as the bit line forcing voltage becomes higher.

14. The nonvolatile memory device of claim 13, wherein the number of program loops having the 1-step verification operation increases as an increment of a program voltage of the ISPP scheme becomes lower.

15. The nonvolatile memory device of claim 8, wherein the memory cell array comprises memory cells each storing at least two bits of data.

16. A memory system, comprising:
a host system; and
a nonvolatile memory device comprising program control logic and a memory cell array that stores data under control of the program control logic,
wherein the memory cell array is programmed by an incremental step pulse programming (ISPP) scheme comprising a plurality of program loops, and
wherein the program control logic performs a program verification operation using a 1-step verification operation in at least one program loop of the plurality of program loops and using a 2-step verification operation in program loops following the at least one program loop among the plurality of program loops.

17. The memory system of claim 16, wherein the 1-step verification operation is performed with a first verification voltage, and the 2-step verification operation is performed with the first verification voltage and a second verification voltage higher than the first verification voltage.

18. The memory system of claim 16, wherein the nonvolatile memory device is located in a memory card.

19. The memory system of claim 18, wherein in the 1-step verification operation, a ground voltage is applied to bit lines connected with memory cells determined to have a threshold voltage lower than the first verification voltage and a program inhibition voltage is applied to bit lines connected with memory cells determined to have a threshold voltage higher than the first verification voltage.

20. The memory system of claim 18, wherein in the 2-step verification operation, a ground voltage is applied to bit lines connected with memory cells determined to have a threshold voltage lower than the first verification voltage, a bit line forcing voltage is applied to bit lines connected with memory cells determined to have a threshold voltage higher than the first verification voltage and lower than the second verification voltage, and a program inhibition voltage is applied to bit lines connected with memory cells determined to have a threshold voltage higher than the second verification voltage.
